(19) United States
(12) Patent Application Publication
(10) Pub. No.: US 2025/0323234 A1
(43) Pub. Date: Oct. 16, 2025

(54) SEMICONDUCTOR PACKAGE AND METHOD

(71) Applicant: Taiwan Semiconductor Manufacturing Co., Ltd., Hsinchu (TW)

(72) Inventors: Tsung-Yen Lee, Hemei Township (TW); Chia-Kuei Hsu, Hsinchu (TW); Ming-Chih Yew, Hsinchu (TW); Shin-Puu Jeng, Hsinchu (TW)

(21) Appl. No.: 19/250,515

(22) Filed: Jun. 26, 2025

Related U.S. Application Data
(62) Division of application No. 17/892,344, filed on Aug. 22, 2022.

(51) Int. Cl. H01L 25/00; H01L 21/48; H01L 21/56; H01L 23/00; H01L 23/31; H01L 23/498; H01L 25/065

(52) U.S. Cl. CPC H01L 25/50; H01L 21/4857; H01L 21/561; H01L 21/568; H01L 23/3185; H01L 23/3192; H01L 23/49833; H01L 23/562; H01L 24/16; H01L 24/19; H01L 24/20; H01L 24/32; H01L 24/73; H01L 24/81; H01L 24/83; H01L 24/92; H01L 24/95; H01L 25/0655; H01L 23/49894; H01L 2224/16238; H01L 2224/19; H01L 2224/2101; H01L 2224/215; H01L 2224/32225; H01L 2224/73204; H01L 2224/81815; H01L 2224/83102; H01L 2224/92125; H01L 2224/95001

(57) ABSTRACT

A method includes forming a first redistribution structure over a carrier, where forming the first redistribution structure includes forming a plurality of first organic polymer layers over the carrier, and forming a plurality of first conductive lines in the plurality of first organic polymer layers, attaching a first package structure to the first redistribution structure, the first package structure including a first semiconductor die, a molding material that surrounds an entirety of a perimeter of the first semiconductor die, and a second redistribution structure on bottom surfaces of the first semiconductor die and the molding material, dispensing a first underfill into a first gap between the plurality of first conductive lines and the first package structure, bonding a substrate to the first redistribution structure using first conductive connectors, and dispensing a second underfill into a second gap between the substrate and the first redistribution structure.

### CROSS-REFERENCE TO RELATED APPLICATIONS

This application is a divisional of U.S. application Ser. No. 17/892,344, filed on Aug. 22, 2022, which application is hereby incorporated herein by reference.

### BACKGROUND

Since the development of the integrated circuit (IC), the semiconductor industry has experienced continued rapid growth due to continuous improvements in the integration density of various electronic components (i.e., transistors, diodes, resistors, capacitors, etc.). For the most part, these improvements in integration density have come from repeated reductions in minimum feature size, which allows more components to be integrated into a given area.

These integration improvements are essentially two-dimensional (2D) in nature, in that the area occupied by the integrated components is essentially on the surface of the semiconductor wafer. The increased density and corresponding decrease in area of the integrated circuit has generally surpassed the ability to bond an integrated circuit chip directly onto a substrate. Interposers have been used to redistribute ball contact areas from that of the chip to a larger area of the interposer. Further, interposers have allowed for a three-dimensional (3D) package that includes multiple chips. Other packages have also been developed to incorporate 3D aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through 17B illustrate cross-sectional views and a top-down view of intermediate stages in the formation of an integrated circuit package according to some embodiments.

FIGS. 18A and 18B illustrate a cross-sectional view and a top-down view of intermediate stages in the formation of an integrated circuit package according to other embodiments.

FIGS. 19A and 19B illustrate a cross-sectional view and a top-down view of intermediate stages in the formation of an integrated circuit package according to other embodiments.

FIGS. 20A and 20B illustrate a cross-sectional view and a top-down view of intermediate stages in the formation of an integrated circuit package according to other embodiments.

FIGS. 21A and 21B illustrate a cross-sectional view and a top-down view of intermediate stages in the formation of an integrated circuit package according to other embodiments.

FIG. 22 illustrates a cross-sectional view of an integrated circuit die in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments include integrated circuit packages and methods for forming the same. An integrated circuit package includes a package component comprising one or more semiconductor chip structures bonded to an interposer (also referred to as a redistribution structure), and a package substrate bonded to a side of the interposer opposing the one or more semiconductor chip structures. Each semiconductor chip structure comprises a molding compound that surrounds a semiconductor chip. In addition, the semiconductor chip structure comprises a redistribution structure that is electrically and physically coupled to a bottom surface of the semiconductor chip, such that the redistribution structure is disposed between the semiconductor chip and the interposer. Advantageous features of such embodiments include a reduction of a mismatch between a co-efficient of thermal expansion of the semiconductor chip structure and a co-efficient of thermal expansion of the interposer. This results in reduced warping of the integrated circuit package and a reduced risk of incomplete physical and electrical coupling of conductive connectors that are used to couple the interposer to the package substrate. In addition, a risk of electrical shorting between adjacent ones of the conductive connectors is reduced. As a result, the reliability and the performance of the integrated circuit package is improved.

Embodiments will now be described with respect to system on chip on wafer (SoCoW) devices in a fan-out package. However, the embodiments described are not intended to limit the embodiments, as the ideas presented may be included in a wide range of embodiments, including any suitable technology generation, all of which are fully intended to be included within the scope.

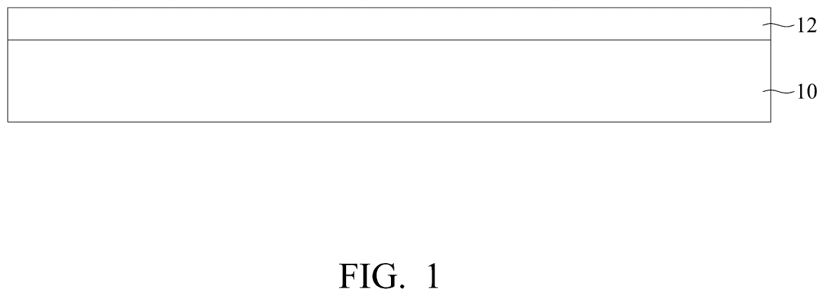

FIGS. 1 through 17B illustrate cross-sectional views and top-down views of intermediate steps during a process for forming a first package component 100, in accordance with some embodiments. FIG. 1 illustrates a carrier 10 and release film 12 formed on the carrier 10. The carrier 10 may be a glass carrier, a silicon wafer, an organic carrier, or the like. The carrier 10 may have a round top-view shape in accordance with some embodiments. The release film 12 may be formed of a polymer-based material and/or an epoxy-based thermal-release material (such as a Light-To-Heat-Conversion (LTHC) material), which is capable of being decomposed under radiation such as a laser beam, so that the carrier 10 may be de-bonded from the overlying structures that will be formed in subsequent processes. In other embodiments, the release film 12 may be an ultra-violet (UV) glue, which loses its adhesive property when exposed to UV lights. The release film 12 may be dispensed as a liquid and cured, may be a laminate film laminated onto the carrier 10, or the like. The top surface of the release film 12 may be leveled and may have a high degree of planarity.

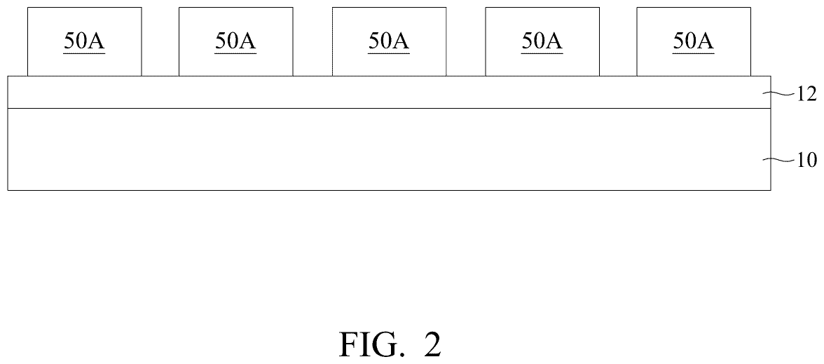

In FIG. 2, package components 50A are attached to the carrier 10 using the release film 12. The package components 50A are bonded to the carrier 10 using, for example, a pick and place process, or other suitable method. In some embodiments, a die attach film (DAF, not separately illustrated) may be placed on a backside of the package components 50A to attach the package components 50A to the release film 12. Each package component 50A may comprise a semiconductor die. In an embodiment, each package component 50A may comprise a System-on-Chip (SoC) die that includes a plurality of device dies packaged as a system, or the like. The device dies may include logic dies, memory dies, input-output dies, Integrated Passive Devices (IPDs), or the like, or combinations thereof. For example, the logic device dies of each package component 50A may be Central Processing Unit (CPU) dies, Graphic Processing Unit (GPU) dies, mobile application dies, Micro Control Unit (MCU) dies, BaseBand (BB) dies, Application processor (AP) dies, or the like. The memory dies of each package component 50A may include Static Random Access Memory (SRAM) dies, Dynamic Random Access Memory (DRAM) dies, or the like. In other embodiments, each package component 50A may comprise an Application Specific Integrated Circuit (ASIC) die.

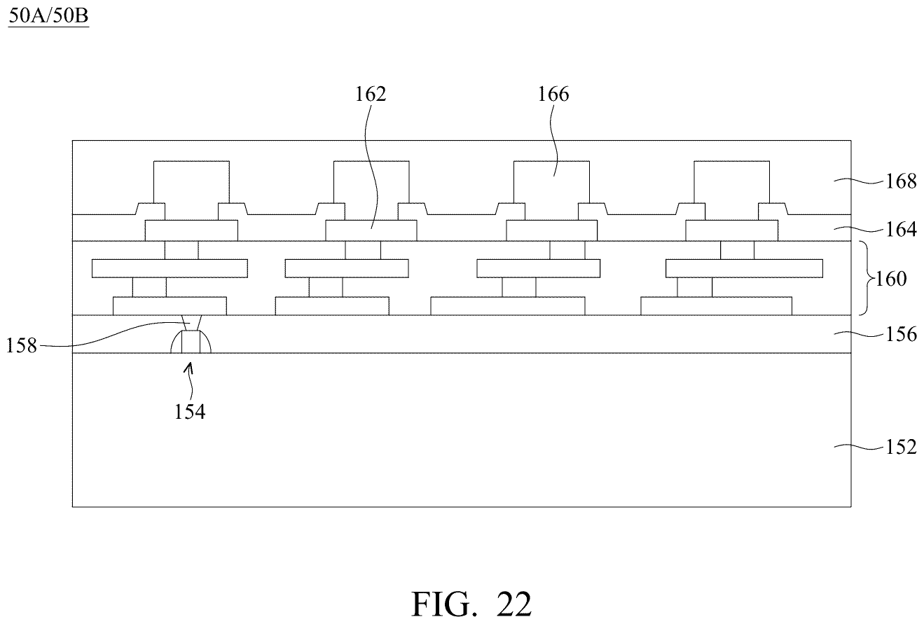

FIG. 22 illustrates a detailed view of an example package component 50A when the package component 50A is a semiconductor die. The package component 50A may be formed in a wafer, which may include different device regions that are singulated in subsequent steps to form a plurality of integrated circuit dies. The package component 50A may be processed according to applicable manufacturing processes to form integrated circuits. For example, the package component 50A includes a semiconductor substrate 152, such as silicon, doped or undoped, or an active layer of a semiconductor-on-insulator (SOI) substrate. The semiconductor substrate 152 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The semiconductor substrate 152 has an active surface (e.g., the surface facing upwards in FIG. 22), sometimes called a front side, and an inactive surface (e.g., the surface facing downwards in FIG. 22), sometimes called a back side.

Devices (represented by a transistor) 154 may be formed at the front surface of the semiconductor substrate 152. The devices 154 may be active devices (e.g., transistors, diodes, etc.), capacitors, resistors, etc. An inter-layer dielectric (ILD) 156 is over the front surface of the semiconductor substrate 152. The ILD 156 surrounds and may cover the devices 154. The ILD 156 may include one or more dielectric layers formed of materials such as Phospho-Silicate Glass (PSG), Boro-Silicate Glass (BSG), Boron-Doped Phospho-Silicate Glass (BPSG), undoped Silicate Glass (USG), or the like.

Conductive plugs 158 extend through the ILD 156 to electrically and physically couple the devices 154. For example, when the devices 154 are transistors, the conductive plugs 158 may couple the gates and source/drain regions of the transistors. Source/drain region(s) may refer to a source or a drain, individually or collectively dependent upon the context. The conductive plugs 158 may be formed of tungsten, cobalt, nickel, copper, silver, gold, aluminum, the like, or combinations thereof. An interconnect structure 160 is over the ILD 156 and conductive plugs 158. The interconnect structure 160 interconnects the devices 154 to form an integrated circuit. The interconnect structure 160 may be formed by, for example, metallization patterns in dielectric layers on the ILD 156. The metallization patterns include metal lines and vias formed in one or more low-k dielectric layers. The metallization patterns of the interconnect structure 160 are electrically coupled to the devices 154 by the conductive plugs 158.

The package component 50A further includes pads 162, such as aluminum pads, to which external connections are made. The pads 162 are on the active side of the package component 50A, such as in and/or on the interconnect structure 160. One or more passivation films 164 are on the package component 50A, such as on portions of the interconnect structure 160 and pads 162. Openings extend through the passivation films 164 to the pads 162. Die connectors 166, such as conductive pillars (for example, formed of a metal such as copper), extend through the openings in the passivation films 164 and are physically and electrically coupled to respective ones of the pads 162. The die connectors 166 may be formed by, for example, plating, or the like. The die connectors 166 electrically couple the respective integrated circuits of the package component 50A.

Optionally, solder regions (e.g., solder balls or solder bumps) may be disposed on the pads 162. The solder balls may be used to perform chip probe (CP) testing on the package component 50A. CP testing may be performed on the package component 50A to ascertain whether the package component 50A is a known good die (KGD). Thus, only package components 50A, which are KGDs, undergo subsequent processing and are packaged, and dies, which fail the CP testing, are not packaged. After testing, the solder regions may be removed in subsequent processing steps.

A dielectric layer 168 may (or may not) be on the active side of the package component 50A, such as on the passivation films 164 and the die connectors 166. The dielectric layer 168 laterally encapsulates the die connectors 166, and the dielectric layer 168 is laterally coterminous with the package component 50A. Initially, the dielectric layer 168 may bury the die connectors 166, such that the topmost surface of the dielectric layer 168 is above the topmost surfaces of the die connectors 166. In some embodiments where solder regions are disposed on the die connectors 166, the dielectric layer 168 may bury the solder regions as well. Alternatively, the solder regions may be removed prior to forming the dielectric layer 168.

The dielectric layer 168 may be a polymer such as PBO, polyimide, BCB, or the like; a nitride such as silicon nitride or the like; an oxide such as silicon oxide, PSG, BSG, BPSG, or the like; the like, or a combination thereof. The dielectric layer 168 may be formed, for example, by spin coating, lamination, chemical vapor deposition (CVD), or the like. In some embodiments, the die connectors 166 are exposed through the dielectric layer 168 during formation of the package component 50A. In some embodiments, the die connectors 166 remain buried and are exposed during a subsequent process for packaging the package component 50A. Exposing the die connectors 166 may remove any solder regions that may be present on the die connectors 166.

In some embodiments, the package component 50A is a stacked device that includes multiple semiconductor substrates 152. For example, the package component 50A may be a memory device such as a hybrid memory cube (HMC) module, a high bandwidth memory (HBM) module, or the like that includes multiple memory dies. In such embodiments, the package component 50A includes multiple semiconductor substrates 152 interconnected by through-substrate vias (TSVs). Each of the semiconductor substrates 152 may (or may not) have an interconnect structure 160.

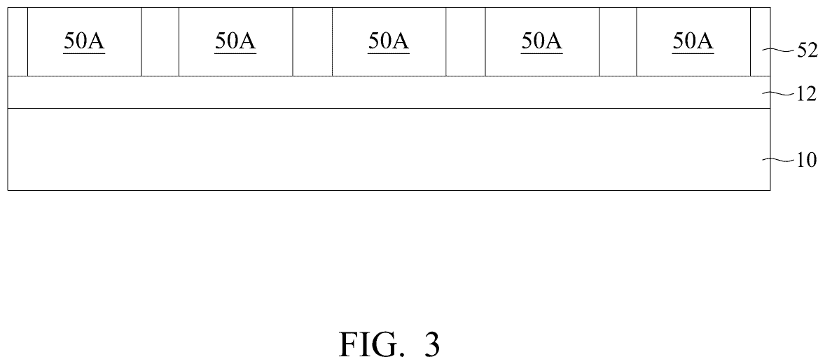

In FIG. 3, a molding material (or molding compound) 52 is formed on top surfaces and sidewalls of the package components 50A and top surfaces of the release film 12. The molding material 52 can comprise a base material (which can be a dielectric material), such as silicon-based material, a resin, a polymer (e.g., epoxy) molding compound that includes fillers (e.g., particles of SiO₂, Al₂O₃ or silica), or the like, that provides electrical isolation between each of the package components 50A and other subsequently formed structures of the first package component 100. The molding material 52 may be formed using any suitable process, such as, spin-coating, a deposition process, an injection process, or the like. Excess portions of the molding material 52 may then be planarized by grinding and CMP to remove a portion of the molding material 52 and expose top surfaces of the package components 50A. As illustrated in FIG. 3, the planarization may result in the top surfaces of the package components 50A being level with top surfaces of the molding material 52.

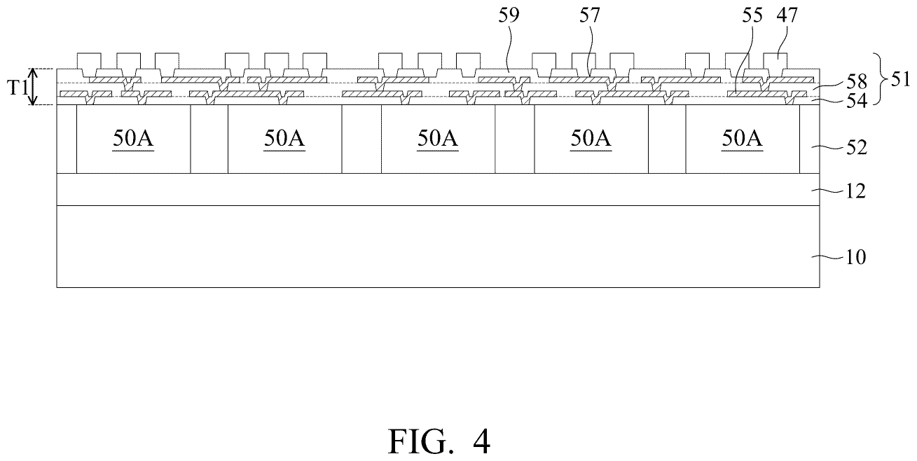

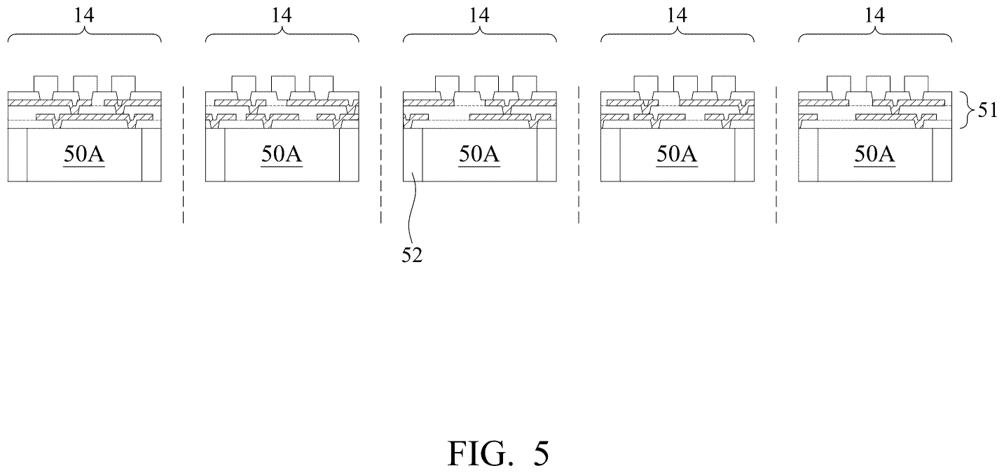

In FIG. 4, a redistribution structure 51 is formed on top surfaces of the package components 50A and the molding material 52. The redistribution structure 51 includes insulating layers 54, 58, and 59; and metallization patterns 55, and 57. The metallization patterns may also be referred to as conductive lines, redistribution layers (RDLs) or redistribution lines. The redistribution structure 51 is shown as an example having three insulating layers and two layers of metallization patterns. However, more or fewer insulating layers and metallization patterns may be formed in the redistribution structure 51. If fewer insulating layers and metallization patterns are to be formed, steps and process discussed below may be omitted. If more dielectric layers and metallization patterns are to be formed, steps and processes discussed below may be repeated.

The insulating layer 54 is deposited on the top surfaces of the package components 50A and the molding material 52. In some embodiments, the insulating layer 54 is formed of or comprises an organic material (e.g., an organic polymer), which may also be a photo-sensitive material such as polybenzoxazole (PBO), polyimide, benzocyclobutene (BCB), or the like. In some embodiments, the insulating layer 54 is formed of or comprises an inorganic dielectric material such as silicon oxide, silicon nitride, silicon carbide, silicon oxynitride, silicon oxycarbide, silicon oxycarbonitride, Un-doped Silicate Glass (USG), or the like. The insulating layer 54 may be formed by spin coating, lamination, CVD, the like, or a combination thereof. The insulating layer 54 is then patterned. The patterning forms openings exposing portions of the die connectors 166 of the package components 50A. The patterning may be by an acceptable process, such as by exposing and developing the insulating layer 54 to light when the insulating layer 54 is a photo-sensitive material or by etching using, for example, an anisotropic etch.

The metallization pattern 55 is then formed. The metallization pattern 55 includes conductive elements extending along the major surface of the insulating layer 54 and extending through the insulating layer 54 to physically and electrically couple to the package component 50A. As an example to form the metallization pattern 55, a seed layer is formed over the insulating layer 54 and in the openings extending through the insulating layer 54. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the metallization pattern 55. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. The combination of the conductive material and underlying portions of the seed layer form the metallization pattern 55. The photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching.

After the formation of the insulating layer 54 and the metallization pattern 55, the insulating layer 58 is deposited on the metallization pattern 55 and the insulating layer 54. The insulating layer 58 may be formed in a manner similar to the insulating layer 54, and may be formed of a similar material as the insulating layer 54.

The metallization pattern 57 is then formed. The metallization pattern 57 includes portions on and extending along the major surface of the insulating layer 58. The metallization pattern 57 further includes portions extending through the insulating layer 58 to physically and electrically couple the metallization pattern 57. The metallization pattern 57 may be formed in a similar manner and of a similar material as the metallization pattern 55. In some embodiments, the metallization pattern 57 has a different size than the metallization pattern 55. For example, the conductive lines and/or vias of the metallization pattern 57 may be wider or thicker than the conductive lines and/or vias of the metallization pattern 55. Further, the metallization pattern 57 may be formed to a greater pitch than the metallization pattern 55.

After the formation of the metallization pattern 57, the insulating layer 59 is deposited on the metallization pattern 57 and the insulating layer 58. The insulating layer 59 may be formed in a manner similar to the insulating layer 58 and the insulating layer 54, and may be formed of a similar material as the insulating layer 58 and the insulating layer 54. In an embodiment, the redistribution structure 51 comprises at least one insulating layer and one metallization pattern. In an embodiment, a thickness T1 of the redistribution structure 51 is in a range from 2 μm to 50 μm. The thickness T1 in the range from 2 μm to 50 μm provides some advantages. These advantages include providing adequate structural support to the molding material 52 that surrounds each package component 50A of a package structure 14 (shown subsequently in FIG. 5). Conductive connectors 47 (which may also be referred to subsequently as UBMS) are formed for external connection to the redistribution structure 51. The conductive connectors 47 have bump portions on and extending along the major surface of the insulating layer 59, and have via portions extending through the insulating layer 59 to physically and electrically couple the metallization pattern 57. As a result, the conductive connectors 47 are electrically coupled to the package components 50A. The conductive connectors 47 may be formed of the same material as the metallization pattern 57.

In FIG. 5, a carrier de-bonding is performed to detach (or “de-bond”) the carrier 10 from the package components 50A and the molding material 52. In accordance with some embodiments, the de-bonding includes projecting a light such as a laser light or an UV light on the release film 12 so that the release film 12 decomposes under the heat of the light and the carrier 10 can be removed. After the carrier 10 is de-bonded from the package components 50A and the molding material 52, a singulation process is then performed by sawing along scribe line regions, e.g., between adjacent package structures 14. The sawing singulates each package structure 14 from an adjacent package structure 14, wherein each package structure 14 comprises a package component 50A and molding compound 52 that surrounds and is in physical contact with an entirety of a perimeter of the package component 50A (e.g., on sidewalls of the package component 50A). In addition, each package structure 14 comprises the insulating layer 54 and the RDL 55 within the insulation layer 54 that is electrically coupled to the package component 50A and physically coupled to the package structure 14.

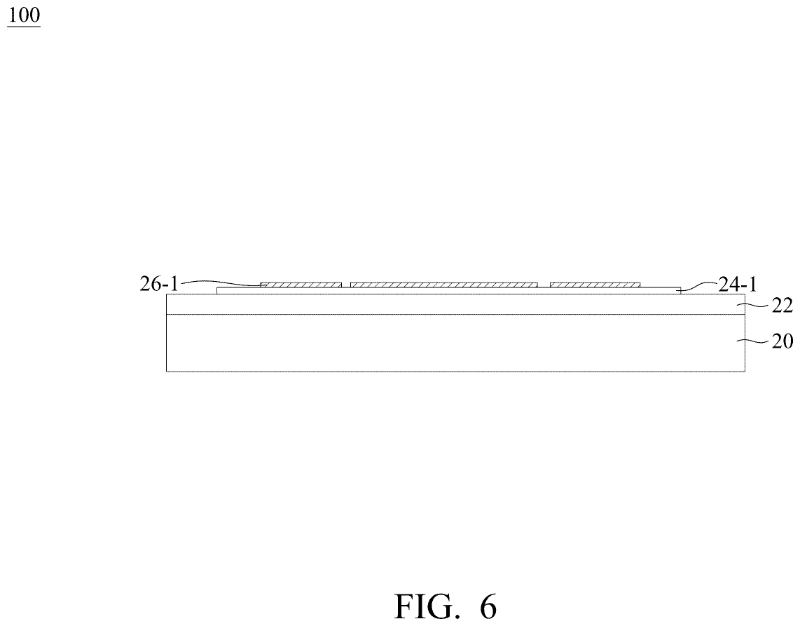

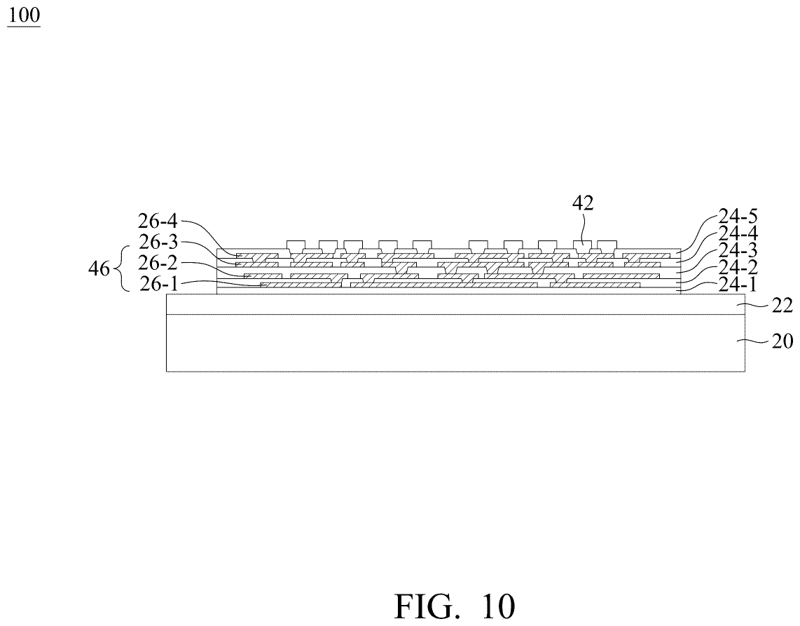

FIGS. 6 through 10 illustrate the formation of a redistribution structure 46 (shown subsequently in FIG. 10). In some embodiments, the redistribution structure 46 may be referred to as an organic interposer. FIG. 6 illustrates a carrier 20 and release film 22 formed on the carrier 20. The carrier 20 may be a glass carrier, a silicon wafer, an organic carrier, or the like. The carrier 20 may have a round top-view shape in accordance with some embodiments. The release film 22 may be formed of a polymer-based material and/or an epoxy-based thermal-release material (such as a Light-To-Heat-Conversion (LTHC) material), which is capable of being decomposed under radiation such as a laser beam, so that the carrier 20 may be de-bonded from the overlying structures that will be formed in subsequent processes. In other embodiments, the release film 22 may be an ultra-violet (UV) glue, which loses its adhesive property when exposed to UV lights. The release film 22 may be dispensed as a liquid and cured, may be a laminate film laminated onto the carrier 20, or the like. The top surface of the release film 22 may be leveled and may have a high degree of planarity.

The redistribution structure 46 (shown subsequently in FIG. 10), includes a plurality of insulating layers 24 and a plurality of RDLs 26 (e.g., conductive lines) that are formed over the release film 22. An insulating layer 24-1, which is one of the insulating layers 24, is formed on the release film 22. In accordance with some embodiments of the present disclosure, the insulating layer 24-1 is formed of or comprises an organic material, which may be a polymer. The organic material may also be a photo-sensitive material. For example, the insulating layer 24-1 may be formed of or comprise polyimide, polybenzoxazole (PBO), benzocyclobutene (BCB), or the like.

A RDL 26-1, which is one of the RDLs 26, is formed on the insulating layer 24-1. The formation of the RDL 26-1 may include forming a metal seed layer (not shown) over the insulating layer 24-1, forming a patterned mask (not shown) such as a photoresist over the metal seed layer, and then performing a metal plating process on the exposed metal seed layer. The patterned mask and the portions of the metal seed layer covered by the patterned mask are then removed, leaving the RDL 26-1 as shown in FIG. 6. In accordance with some embodiments of the present disclosure, the metal seed layer includes a titanium layer and a copper layer over the titanium layer. In an embodiment, the plated metal comprises copper, aluminum, or the like. The metal seed layer may be formed using, for example, Physical Vapor Deposition (PVD) or a like process. The plating may be performed using, for example, a chemical electrical plating process.

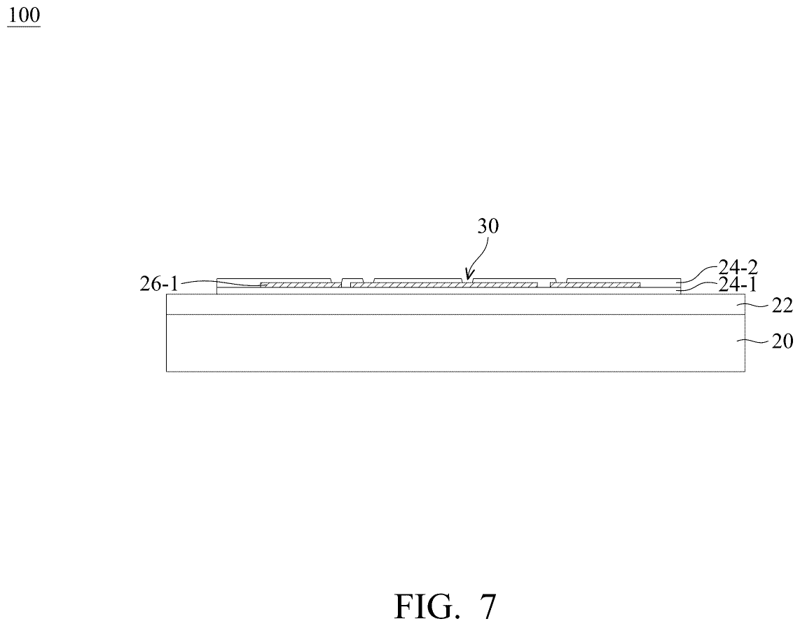

FIGS. 7 through 10 illustrate the formation of additional insulating layers 24 (including insulating layers 24-2, 24-3, 24-4 and 24-5, for example) and additional RDLs 26 (including RDLs 26-2, 26-3 and 26-4, for example). In FIG. 7, the insulating layer 24-2 is first formed on the RDL 26-1. The bottom surface of the insulating layer 24-2 is in contact with top surfaces of the RDL 26-1 and the insulating layer 24-1. The insulating layer 24-2 may be formed of or comprise an organic dielectric material, which may be a polymer. For example, the insulating layer 24-2 may comprise a photo-sensitive material such as PBO, polyimide, BCB, or the like. The insulating layer 24-2 is then patterned to form via openings (occupied by via portions of subsequently formed RDL 26-2) therein. Hence, some portions of the RDL 26-1 are exposed through the openings in the insulating layer 24-2.

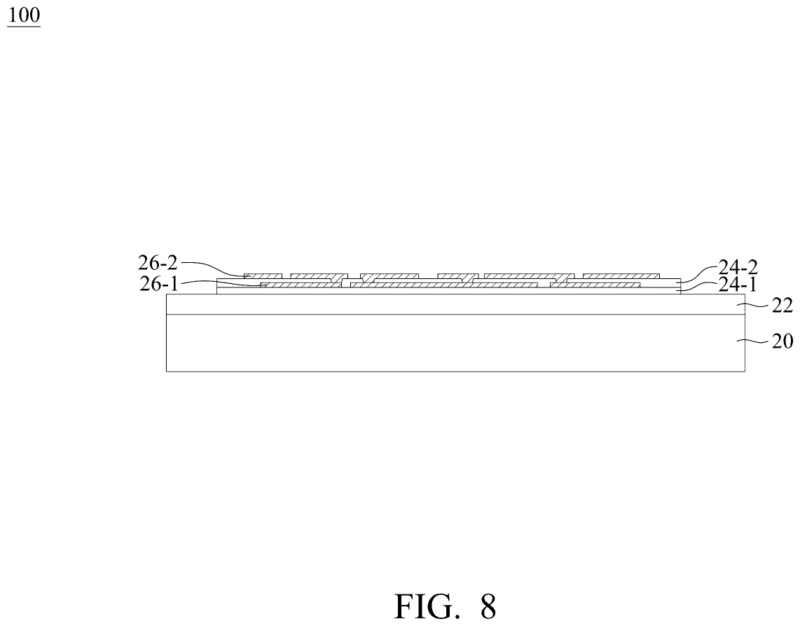

In FIG. 8, the RDL 26-2 is formed on the insulating layer 24-2, wherein the RDL 26-2 is electrically connected to the RDL 26-1. The RDL 26-2 includes via portions extending into the openings in the insulating layer 24-2, and trace portions (metal line portions) over the insulating layer 24-2. In accordance with some embodiments, the formation of the RDL 26-2 may include depositing a blanket metal seed layer extending into the via openings, and forming and patterning a plating mask (such as a photoresist), with openings formed in the plating mask and directly over the via openings. A plating process is then performed to plate a metallic material, which fully fills the via openings, and has some portions higher than a top surface of the insulating layer 24-2. The plating mask is then removed, followed by an etching process to remove the exposed portions of the metal seed layer, which was previously covered by the plating mask. The remaining portions of the metal seed layer and the plated metallic material form the RDL 26-2. The RDL 26-2 includes metal trace portions and via portions (also referred to as vias). The trace portions are over the insulating layer 24-2, and the via portions are in the insulating layer 24-2. Each of the vias may have a tapered profile, with the upper portions wider than the corresponding lower portions. The metal seed layer and the plated material may be formed of the same material or different materials. For example, the metal seed layer may include a titanium layer, and a copper layer over the titanium layer. The plated metallic material of the RDL 26-2 may include a metal or a metal alloy including copper, aluminum, tungsten, or the like, or alloys thereof.

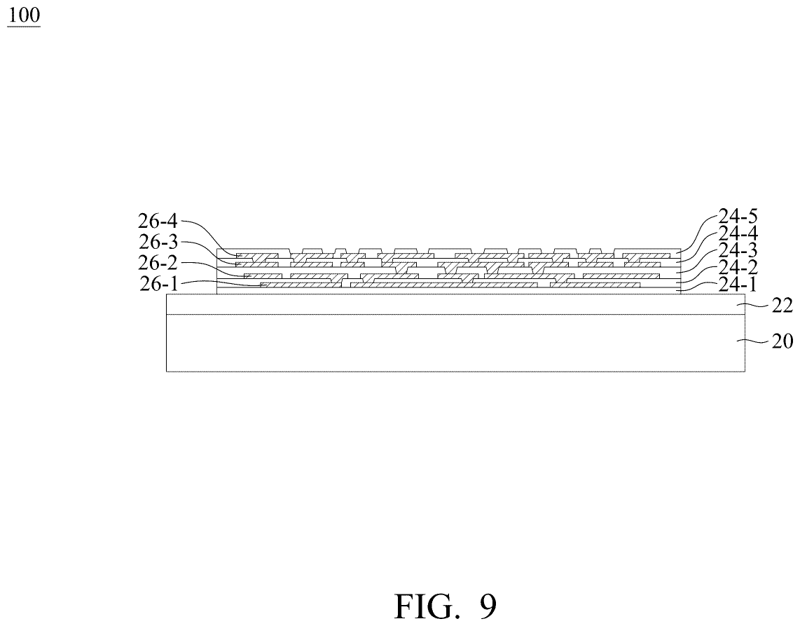

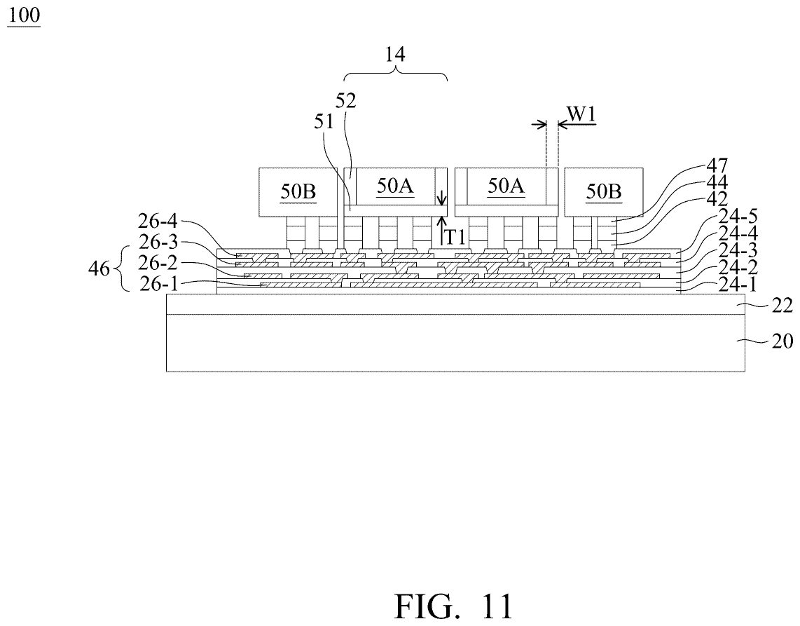

FIG. 9 illustrates that after the formation of the RDL 26-2, there may be more insulating layers and corresponding RDLs formed, with the upper RDLs over and landing on the respective lower RDLs. For example, FIG. 9 illustrates insulating layers 24-3, 24-4 and 24-5, and RDLs 26-3 and 26-4 as an example. It is appreciated that there may be more insulating layers and RDLs formed. In an embodiment, the redistributions structure 46 (shown subsequently in FIG. 10) comprises at least 4 RDLs and at least 5 insulating layers. The redistribution structure 46 comprising at least 4 RDLs and at least 5 insulating layers provides some advantages. These advantages include providing adequate structural support to the subsequently bonded package structures 14 and package components 50B (shown subsequently in FIG. 11). The material of the insulating layers 24-3, 24-4 and 24-5 may be selected from the same group (or different group) of candidate materials as dielectric layers 24-1 and 24-2. For example, insulating layers 24-3, 24-4 and 24-5 may be formed of an organic material, which may be a polymer such as polyimide, PBO, BCB, or the like. The RDLs 26-3 and 26-4 may also be formed of similar materials, and using similar formation processes, as the RDLs 26-1 and 26-2.

A topmost insulating layer of the insulating layers 24, for example, the insulating layer 24-5 is patterned using acceptable photolithography and etching techniques to form openings in the insulating layer 24-5 that expose a topmost RDL of the RDLs 26, for example, the RDL 26-4. The locations of the openings in insulating layer 24-5 correspond to the locations in which conductive connectors 42 (shown subsequently in FIG. 10) are to be formed for electrical connection of the redistribution structure 46 to other package components in a subsequent step.

In FIG. 10, the conductive connectors 42 may be formed. In an embodiment the conductive connectors 42 may be microbumps, ball grid array (BGA) connectors, solder balls, metal pillars, controlled collapse chip connection (C4) bumps, electroless nickel-electroless palladium-immersion gold technique (ENEPIG) formed bumps, or the like. The conductive connectors 42 may include a conductive material such as solder, copper, aluminum, gold, nickel, silver, palladium, tin, the like, or a combination thereof. In some embodiments, the conductive connectors 42 are formed by initially forming a layer of solder through evaporation, electroplating, printing, solder transfer, ball placement, or the like. Once a layer of solder has been formed on the structure, a reflow may be performed in order to shape the material into the desired bump shapes.

In another embodiment, the conductive connectors 42 comprise metal pillars (such as a copper pillar) formed by sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

In other embodiments, the redistribution structure 46 can be replaced by a semiconductor-comprising illustrated in the Figures). The semiconductor-comprising interposer may comprise a bulk semiconductor substrate, SOI substrate, multi-layered semiconductor substrate, or the like. The semiconductor material of the substrate may be silicon, germanium, a compound semiconductor including silicon germanium, silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The semiconductor-comprising interposer may comprise a substrate that is doped or undoped. In some embodiments, the semiconductor-comprising interposer will not include active devices therein, although the semiconductor-comprising interposer may include passive devices formed in and/or on a first surface of the substrate.

The semiconductor-comprising interposer may comprise through-vias (TVs) that extend from the first surface of the substrate to a second surface of the substrate. The TVs are also sometimes referred to as through-substrate vias or through-silicon vias when the substrate is a silicon substrate. The interposer may also comprise a redistribution structure over the first surface of the substrate, wherein the redistribution structure is electrically connected to the TVs of the substrate. In some embodiments, the redistribution structure may be formed using one or more methods similar to those described above with respect to the redistribution structure 46 and/or the interconnect structure 160.

In FIG. 11, one or more package structures 14 and one or more package components 50B are bonded to the redistribution structure 46. Each package component 50B may be a semiconductor die similar to the package component 50A that was described above with respect to FIG. 22. Each of the package components 50B may include system on chip dies, logic dies, DRAM dies, SRAM dies, central processing unit dies, I/O dies, combinations of these, or the like. For example, each package component 50B may comprise a memory die such as a DRAM die (e.g., a high bandwidth memory (HBM) die), or the like. The memory dies may be discrete memory dies, or may be in the form of a die stack that includes a plurality of stacked memory dies. In some embodiments, the package components 50B are bare dies (sometimes referred to as bare chips), and are semiconductor dies that have not be encapsulated or otherwise include fan-out redistribution structures.

In some embodiments, the package structures 14 and the package components 50B are bonded to the redistribution structure 46 using conductive connectors 44, such as solder, or the like. For example, solder may be placed on the conductive connectors 47 of the package structures 14 and the package components 50B or the conductive connectors 42, and package structures 14 and the package components 50B may be placed on the conductive connectors 42 and a reflow process performed. Conductive connectors 44 may also include non-solder metal pillars, or metal pillars and solder caps over the non-solder metal pillars, which may also be formed through plating. Other types of bonding, such as metal-to-metal direct bonding, hybrid bonding (including both of dielectric-to-dielectric bonding and metal-to-metal direct bonding), or the like may also be used. The conductive connectors 47 are electrically connected to the redistribution structure 51 of each package structure 14.

It is appreciated that while FIG. 11 illustrates two package structures 14 and two package components 50B coupled to the redistribution structure 46, other numbers of the package structures 14 and the package components 50B may be coupled to the redistribution structure 46. The package structure 14 comprises the molding material 52 that surrounds an entirety of a perimeter of the package component 50A (e.g., on sidewalls of the package component 50A). In an embodiment, a width W1 of the molding material from a point adjacent to a sidewall of the package component 50A to a point on an outermost sidewall of the package structure 14 is in a range from 10 μm to 500 μm, wherein the sidewall of the package component 50A is parallel to the outermost sidewall of the package structure 14. Having the width W1 in a range from 10 μm to 500 μm is advantageous in that the width W1 can be used to tune a combined co-efficient of thermal expansion of each of the package structures 14 in order to reduce a mismatch between the co-efficient of thermal expansion of each of the package structures 14 and a co-efficient of thermal expansion of the redistribution structure 46. This results in reduced warping of the first package component 100. In an embodiment, top surfaces of the package structures 14 may be level with top surfaces of the package components 50B. In other embodiments, the top surfaces of the package structures 14 may be higher than or lower than the top surfaces of the package components 50B.

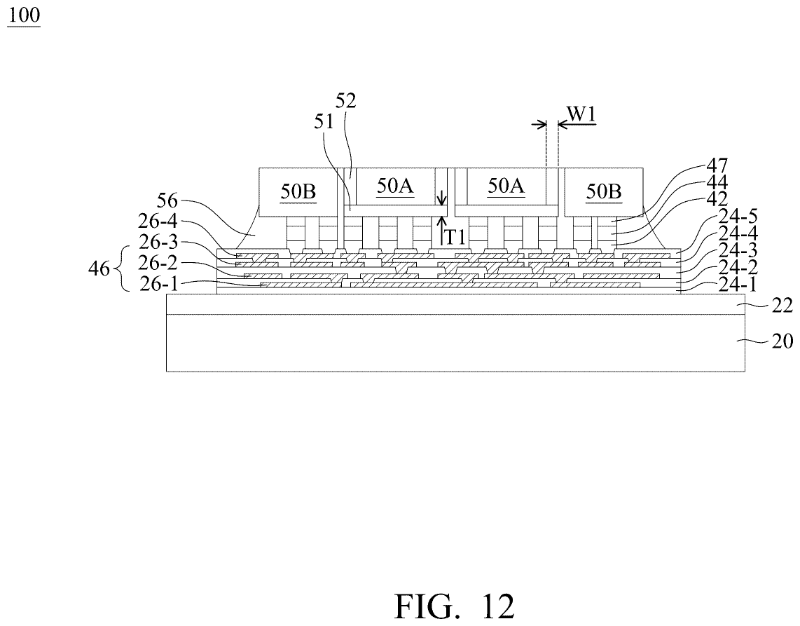

In FIG. 12, an underfill 56 is formed between package structures 14 and the redistribution structure 46, as well as between the package components 50B and the redistribution structure 46. In addition, the underfill 56 may also fill gaps between sidewalls of adjacent package structures 14. The underfill 56 may also fill gaps between each package structure 14 and an adjacent package component 50B. In some embodiments, the underfill 56 includes a base material, such as an epoxy, and filler particles in the epoxy, and may be deposited by a capillary flow process after the package structures 14 and the package components 50B are attached or may be formed by a suitable deposition method before the package structures 14 and the package components 50B are attached. Some example base materials include epoxy-amine, epoxy anhydride, epoxy phenol, or the like, or the combinations thereof. The filler particles may be formed of a dielectric material, and may include silica, alumina, boron nitride, or the like, which may be in the form of spherical particles. The underfill 56 may undergo a curing process after being formed. FIG. 12 shows an embodiment where the underfill 56 has a flat top surface level with top surfaces of the package structures 14 and the package components 50B. In some embodiments, the top surface of underfill 56 may not be flat and may be lower than the top surfaces of package structures 14 and the package components 50B. There may be a distinguishable interface between the underfill 56 and the molding material 52.

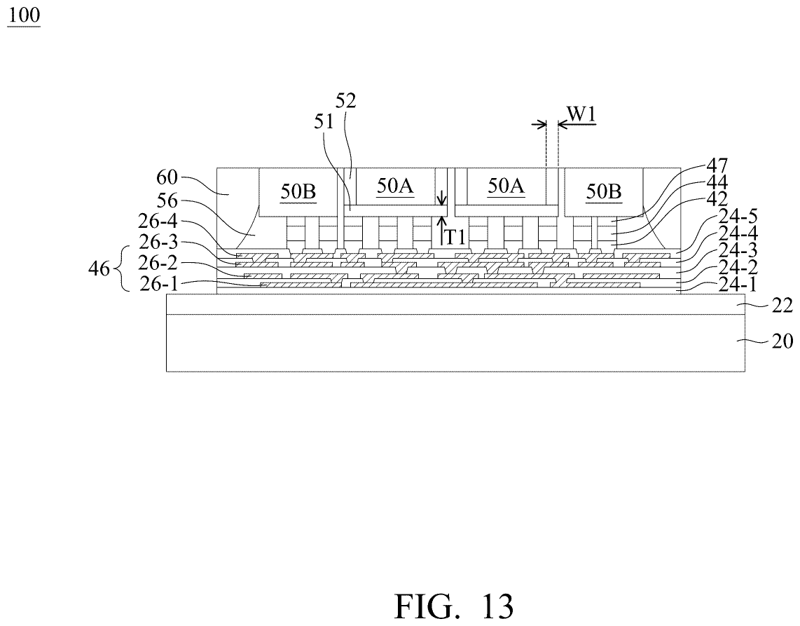

In FIG. 13, package components 50, and the package structures 14 are encapsulated in an encapsulant 60. The encapsulant 60 may be applied by compression molding, transfer molding, or the like, and may be formed over the first package component 100, such that package components 50B and package structures 14 are buried or covered. The encapsulant 60 may be applied in liquid or semi-liquid form and subsequently cured, for example, at a temperature in a range between about 120° C. and about 180° C. The encapsulant 60 may include a molding compound, a molding underfill, an epoxy, and/or a resin. The molding compound may include a base material, which may be a polymer, a resin, an epoxy, or the like, and filler particles in the base material. The filler particles may be dielectric particles of SiO₂, Al₂O₃, silica, or the like, and may have spherical shapes. Also, the spherical filler particles may have the same or different diameters.

The encapsulant 60 may further surround the underfill 56. There may be a distinguishable interface between underfill 56 and the encapsulant 60. In an embodiment, a base material of the molding material 52 is different from a base material of the underfill 56. In an embodiment, a filler material of the molding material 52 may be different from a filler material of the underfill 56.

In a subsequent process, a planarization process such as a Chemical Mechanical Polish (CMP) process or a mechanical grinding process is performed to polish the encapsulant 60. Top surfaces of the package components 50B and the package structures 14 may be exposed as a result of the planarization process.

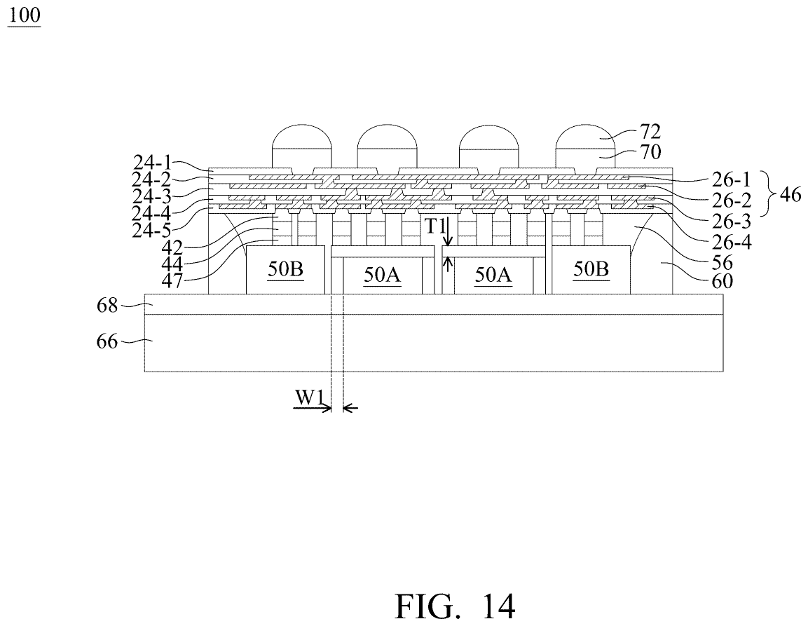

FIG. 14 illustrates a carrier swap and the formation of conductive connectors on a side of the redistribution structure 46. A carrier 66 is attached to surfaces of the encapsulant 60 and exposed surfaces of the package components 50B and the package structures 14 using release film 68. The carrier 20, shown in FIG. 13, is detached from the first package component 100. The detaching process may include projecting a light beam, such as a laser beam, or UV light, on the release film 22 shown in FIG. 13, and the light beam penetrates through the carrier 20, which may be transparent. As a result of the light-exposure, such as the laser scanning, release film 22 is decomposed by the heat of the light beam, and carrier 20 may be lifted off from the release film 22. The corresponding process is also referred to as the de-bonding.

As a result of the de-bonding process, the insulating layer 24-1 is exposed. UBMs 70 and conductive connectors 72 are formed on the redistribution structure 46. The formation process may include patterning the insulating layer 24-1 to form openings that expose the RDL 26-1, and forming UBMs 70, which extend into the openings in the insulating layer 24-1. The UBMs 70 may be formed by first depositing a conductive metal using any suitable method, for example, sputtering, evaporation, PECVD, or the like. Suitable photolithographic masking and etching process are then used to remove portions of the conductive metal, and the remaining portions of the conductive metal form the UBMs 70. UBMs 70 may be formed of or comprise nickel, copper, titanium, or multi-layers thereof. In some embodiments, each of UBMs 70 includes a titanium layer and a copper layer over the titanium layer.

Conductive connectors 72 are formed on the UBMs 70. The formation of the conductive connectors 72 may include placing solder balls on the exposed portions of the UBMs 70, and reflowing the solder balls, and hence the conductive connectors 72 are solder regions. The conductive connectors 72 may also include non-solder metal pillars, or metal pillars and solder caps over the non-solder metal pillars, which may also be formed through plating.

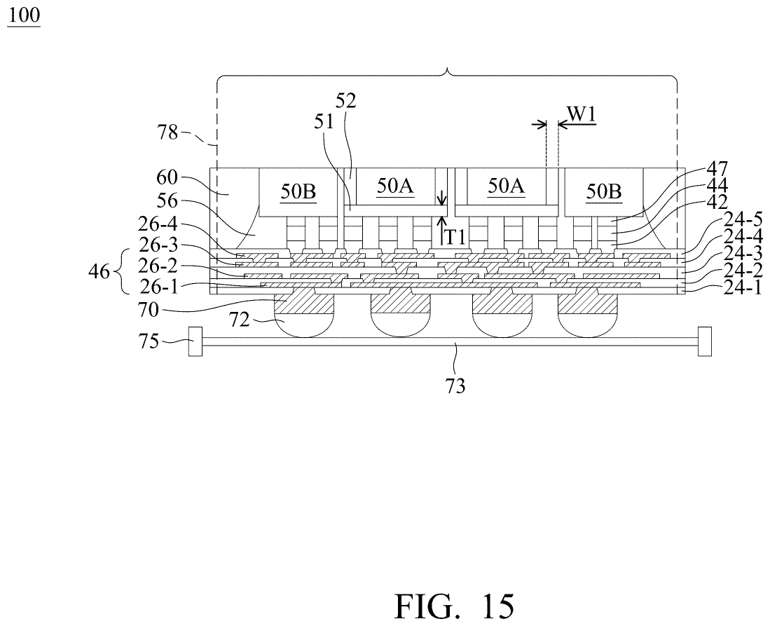

In FIG. 15, the carrier 66 is detached from the first package component 100. The detaching process may include projecting a light beam, such as a laser beam, or UV light, on the release film 68 shown in FIG. 14, and the light beam penetrates through the carrier 66, which may be transparent. As a result of the light-exposure, such as the laser scanning, the release film 68 is decomposed by the heat of the light beam, and carrier 66 may be lifted off from the release film 68. The wafer structure of the first package component 100 is placed on tape 73, which is supported by a frame 75. The wafer structure is then singulated along scribe lines 78, so that the wafer structure is separated into discrete package structures.

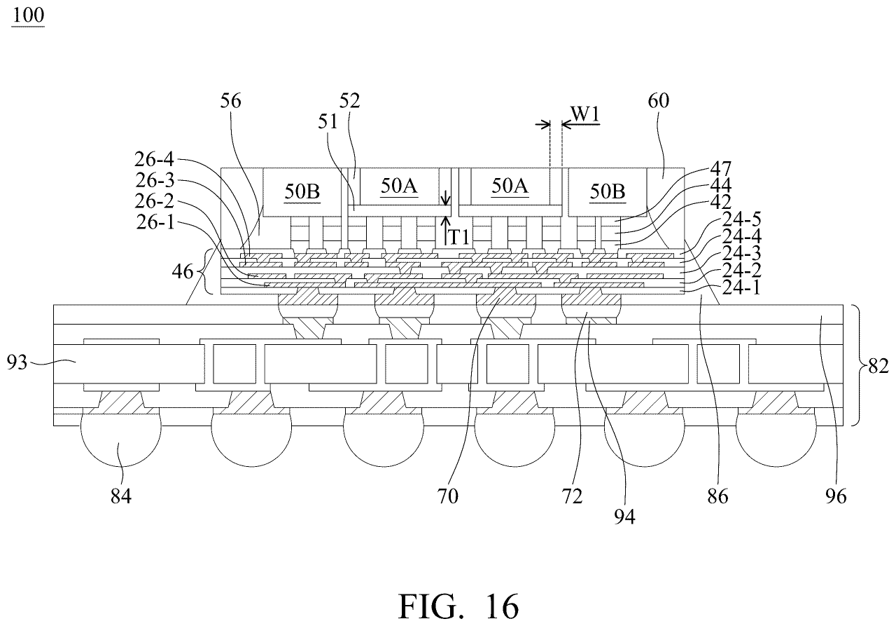

In FIG. 16, the first package component 100 is then bonded to a package component 82. The bonding is via the conductive connectors 72, which may include solder regions. The package component 82 may be or may comprise an interposer, a package, a core substrate, a coreless substrate, a printed circuit board, or the like. FIG. 16 shows an embodiment where package component 82 includes a substrate core 93 and bond pads 94 over the substrate core 93. The substrate core 93 may be made of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. Additionally, the substrate core 93 may be an SOI substrate. Generally, an SOI substrate includes a layer of a semiconductor material such as epitaxial silicon, germanium, silicon germanium, SOI, SGOI, or combinations thereof. The substrate core 93 is, in one alternative embodiment, based on an insulating core such as a fiberglass reinforced resin core. One example core material is fiberglass resin such as FR4. Alternatives for the core material include bismaleimide-triazine BT resin, or alternatively, other PCB materials or films. Build up films such as ABF or other laminates may be used for substrate core 93.

The substrate core 93 may include active and passive devices (not shown). A wide variety of devices such as transistors, capacitors, resistors, combinations of these, and the like may be used to generate the structural and functional requirements of the design for the device stack. The devices may be formed using any suitable methods.

The substrate core 93 may also include metallization layers and vias (not shown), with the bond pads 94 being physically and/or electrically coupled to the metallization layers and vias. The metallization layers may be formed over the active and passive devices and are designed to connect the various devices to form functional circuitry. The metallization layers may be formed of alternating layers of dielectric material (e.g., low-k dielectric material) and conductive material (e.g., copper) with vias interconnecting the layers of conductive material and may be formed through any suitable process (such as deposition, damascene, dual damascene, or the like). In some embodiments, the substrate core 93 is substantially free of active and passive devices.

In some embodiments, the conductive connectors 72 are reflowed to attach the first package component 100 to the bond pads 94. The conductive connectors 72 electrically and/or physically couple the package component 82, including metallization layers in the substrate core 93, to the package component 82. In some embodiments, a solder resist 96 is formed on the substrate core 93. The conductive connectors 72 may be disposed in openings in the solder resist 96 to be electrically and mechanically coupled to the bond pads 94. The solder resist 96 may be used to protect areas of the substrate core 93 from external damage.

The conductive connectors 72 may have an epoxy flux (not shown) formed thereon before they are reflowed with at least some of the epoxy portion of the epoxy flux remaining after the first package component 100 is attached to the package component 82. This remaining epoxy portion may act as an underfill to reduce stress and protect the joints resulting from reflowing the conductive connectors 72. An underfill 86 may be dispensed into the gap between the redistribution structure 46 and the package component 82. The underfill 86 may also be disposed on sidewalls of the redistribution structure 46. In accordance with some embodiments, underfill 86 includes a base material and filler particles mixed in the base material. The base material may include a resin, an epoxy, and/or a polymer. Some example base materials include epoxy-amine, epoxy anhydride, epoxy phenol, or the like, or the combinations thereof. The filler particles are formed of a dielectric material, and may include silica, alumina, boron nitride, or the like, which may be in the form of spherical particles. Underfill 86 may be dispensed in a flowable form, and is then cured.

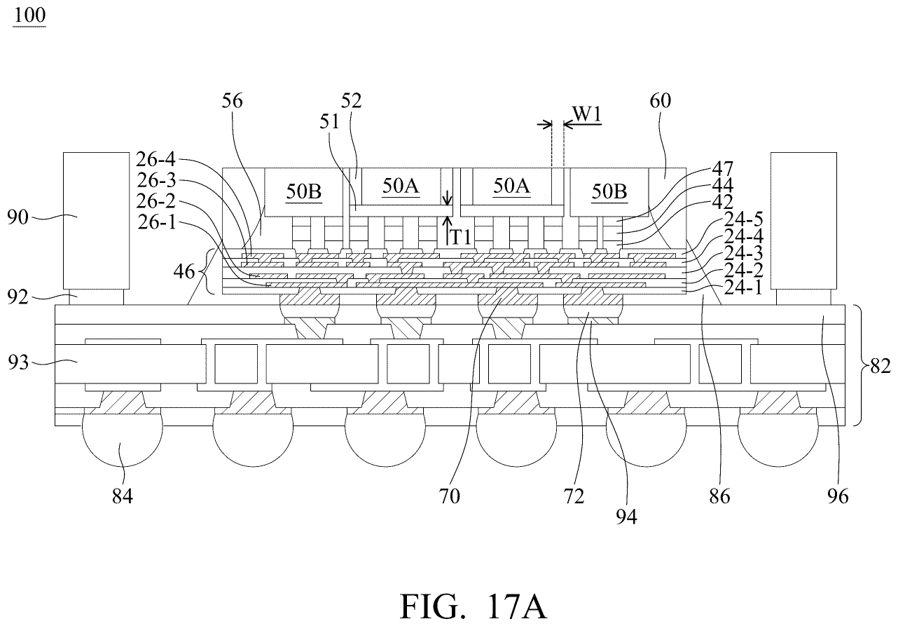

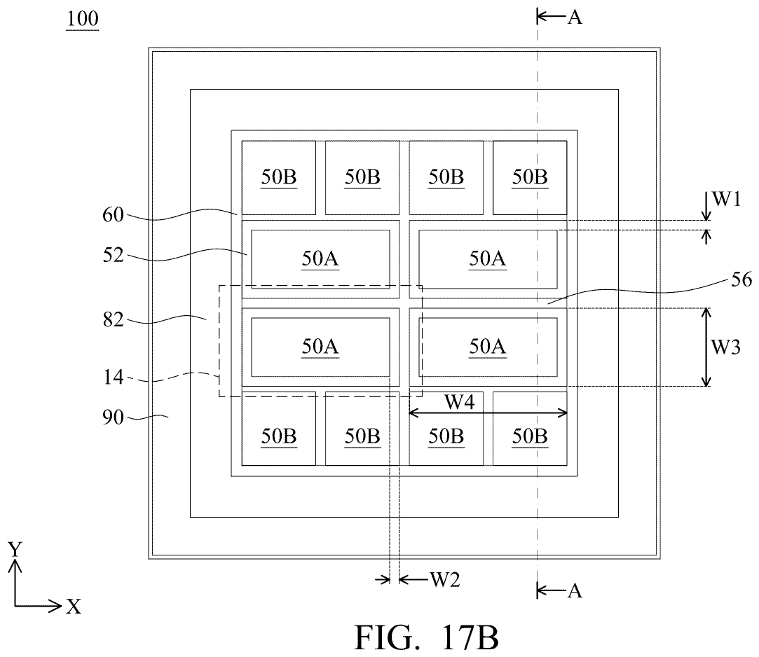

FIG. 17A illustrates a cross-sectional view of the first package component 100 along a line A-A shown in FIG. 17B. In FIG. 17A, a stiffener ring 90 is attached to the package component 82, in accordance with some embodiments. The stiffener ring 90 is used to provide additional support to the package component 82 during subsequent manufacturing processes and usage. The stiffener ring 90 may be placed on the package component 82 so that stiffener ring 90 surrounds and encircles the package structures 14, the package components 50B, the underfill 56, the underfill 86 and the encapsulant 60. In some embodiments, stiffener ring 90 may comprise a dielectric material (e.g., silicone, or other suitable dielectric material), a metal (e.g., copper, aluminum, or other suitable metal), or the like. The stiffener ring 90 may be attached to the package component 82 using an adhesive 92 such as an epoxy, glue, polymeric material, solder paste, thermal adhesive, or the like.

FIG. 17B illustrates a top-down view of the first package component 100 shown in FIG. 17A. The FIG. 17B illustrates a first axis (e.g., the x-axes) and a second axes (e.g., the y-axes), wherein the first axis and the second axis are orthogonal to each other. The first package component 100 may comprise four package structures 14 disposed in a 2×2 type configuration. In an embodiment, a portion of the molding material 52 adjacent to and in physical contact with sidewalls of each package component 50A has the width W1 that is in a range from 10 μm to 500 μm when measured in a direction parallel to the second axis (e.g., the y-axis). In an embodiment, a portion of the molding material 52 adjacent to and in physical contact with sidewalls of each package component 50A has a width W2 that is in a range from 10 μm to 500 μm when measured in a direction parallel to the first axis (e.g., the x-axis). In an embodiment, the width W1 is equal to the width W2. In an embodiment, the width W1 is greater than the width W2. In an embodiment, the width W1 is smaller than the width W2. Different widths W1 and W2 can be used to tune a combined co-efficient of thermal expansion of the package structure 14 in order to reduce a mismatch between the co-efficient of thermal expansion of the package structure 14 and a co-efficient of thermal expansion of the redistribution structure 46. The thermal co-efficient of thermal expansion of the package structure 14 can be increased by increasing the widths W1 and width W2, In addition, an increase in the width W2 will lead to a proportional increase of the thermal co-efficient of thermal expansion of the package structure 14 along the first axis (e.g., the x-axis) and an increase in the width W1 will lead to a proportional increase of the thermal co-efficient of thermal expansion of the package structure 14 along the second axis (e.g., the y-axis). In this way tuning of thermal co-efficient of thermal expansion of the package structure 14 along each of the first axis (e.g., the x-axis) and the second axis (e.g., the y-axis) is possible.

In an embodiment, the four package structures are arranged such that edges of each package structure 14 having widths W3 are oriented parallel to the second axis (e.g., the y-axis) and edges of each package structure 14 having widths W4 are oriented to be parallel to the first axis (e.g., the x-axis), wherein the width W4 is greater than the width W3. In addition, two package components 50B may be adjacent to each of the package structures 14, such that the two package components 50B are adjacent to an edge of each package structure 14 that has the width W4. The package structures 14 are physically isolated from each other and from the package components 50B by the underfill 56. In addition, the package components 50B are physically isolated from each other by the underfill 56. Although four package structures 14 and eight package components 50B are illustrated in FIG. 17B, the first package component 100 may comprise any number of package structures 14 and package components 50B that are disposed in any configuration.

Advantages can be achieved as a result of a method for the formation of the first package component 100 comprising one or more package structures 14 bonded to the redistribution structure 46. Each package structure 14 comprises a package component 50A and the molding material 52 that surrounds the package component 50A (e.g., on sidewalls of the package component 50A), such that the molding material 52 adjacent to sidewalls of the package component 50A has the width W2 that is in a range from 10 μm to 500 μm when measured in a direction parallel to the first axis (e.g., the x-axis), and the molding material 52 adjacent to sidewalls of the package component 50A has the width W1 that is in a range from 10 μm to 500 μm when measured in a direction that is parallel to the second axis (e.g., the y-axis). Different widths W1 and W2 can be used to tune a combined co-efficient of thermal expansion of the package structure 14 in order to reduce a mismatch between the co-efficient of thermal expansion of the package structure 14 and a co-efficient of thermal expansion of the redistribution structure 46. For example, it has been observed that packages having W1 and W2 as described above have reduced co-efficient of thermal expansion mismatch. This results in reduced warping of the first package component 100 and a reduced risk of incomplete physical and electrical coupling of the conductive connectors 72 that are used to couple the redistribution structure 46 to the package component 82. In addition, each package structure 14 comprises the redistribution structure 51 that is electrically and physically coupled to a bottom surface of a package component 50A of the package structure 14. The redistribution structure 51 comprises the thickness T1 in a range from 2 μm to 50 μm and provides structural support to the molding material 52 that surrounds each package component 50A of a package structure 14.

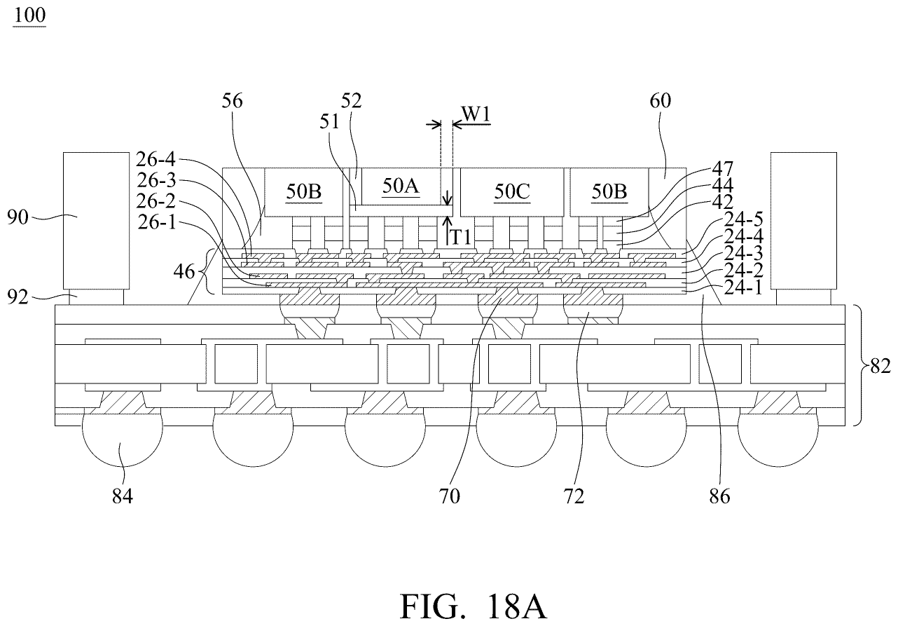

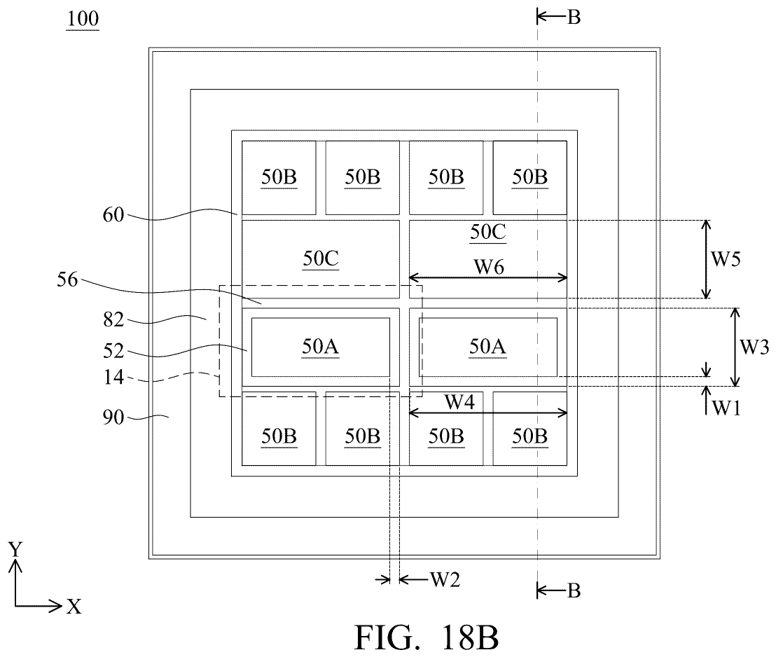

FIGS. 18A and 18B illustrate the first package component 100 in accordance with some other embodiments. Unless specified otherwise, like reference numerals in this embodiment (and subsequently discussed embodiments) represent like components in the embodiment shown in FIGS. 1 through 17B formed by like processes. Accordingly, the process steps and applicable materials may not be repeated herein.

FIG. 18A illustrates a cross-sectional view of the first package component 100 along a line B-B shown in FIG. 18B. FIG. 18B illustrates a top-down view of the first package component 100 shown in FIG. 18A. The FIG. 18B is illustrated to show a first axis (e.g., the x-axis) and a second axis (e.g., the y-axis), wherein the first axis and the second axis are orthogonal to each other. The first package component 100 may comprise two package structures 14 and two package components 50C disposed in a 2×2 type configuration. The package components 50C may be similar to the package components 50A described previously in FIG. 2, and do not comprise the molding material 52, the insulating layer 54 and the RDL 55 of the package structure 14. In an embodiment, the two package structures 14 are arranged such that edges of each package structure 14 having widths W3 are oriented to be parallel to the second axis (e.g., the y-axis) and edges of each package structure 14 having widths W4 are oriented to be parallel to the first axis (e.g., the x-axis), wherein the width W4 is greater than the width W3. The two package components 50C are arranged such that edges of each package component 50C having widths W5 are oriented to be parallel to the second axis (e.g., the y-axis) and edges of each package component 50C having widths W6 are oriented to be parallel to the first axis (e.g., the x-axis), wherein the width W6 is greater than the width W5. The two package structures 14 are disposed such that one sidewall having the width W3 of each package structures 14 is adjacent to another sidewall having the width W3 of the adjacent package structure 14. The two package components 50C are disposed such that one sidewall having the width W5 of each package component 50C is adjacent to another sidewall having the width W5 of the adjacent package component 50C. In addition, two package components 50B may be adjacent to each of the package structures 14 and the package components 50C, such that two package components 50B are adjacent to an edge of each package structure 14 that has the width W4, and two package components 50B are adjacent to an edge of each package component 50C that has the width W6. Each package structure 14 is physically isolated from the other package structure 14, the package components 50B and the package components 50C by the underfill 56. Each package component 50C is physically isolated from the other package component 50C, the package structures 14 and the package components 50B by the underfill 56. In addition, the package components 50B are physically isolated from each other by the underfill 56.

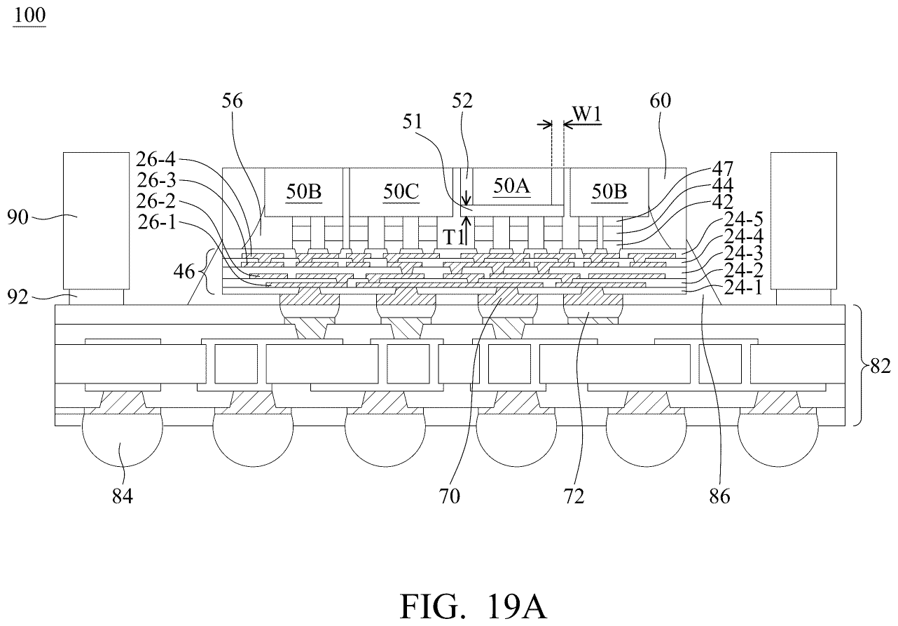

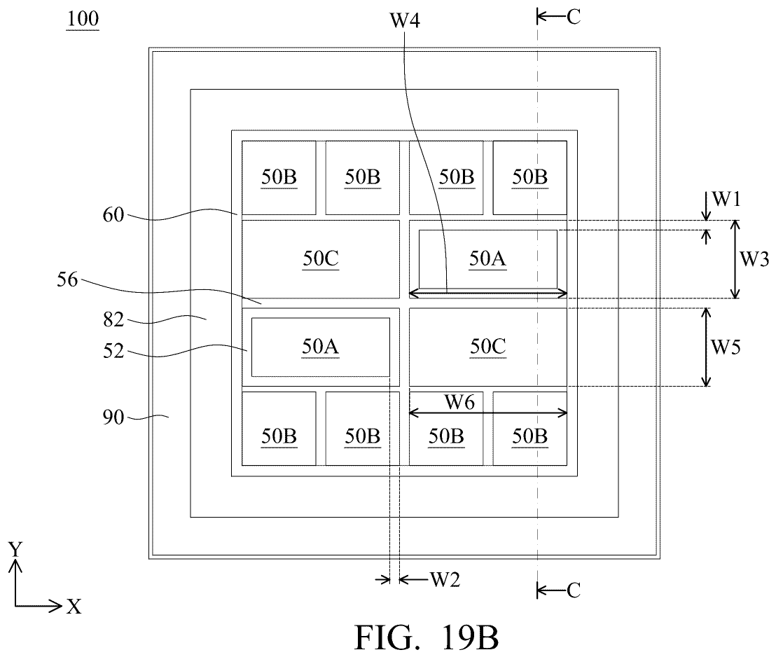

FIGS. 19A and 19B illustrate the first package component 100 in accordance with some other embodiments. Unless specified otherwise, like reference numerals in this embodiment (and subsequently discussed embodiments) represent like components in the embodiment shown in FIGS. 1 through 18B formed by like processes. Accordingly, the process steps and applicable materials may not be repeated herein.

FIG. 19A illustrates a cross-sectional view of the first package component 100 along a line C-C shown in FIG. 19B. FIG. 19B illustrates a top-down view of the first package component 100 shown in FIG. 19A. The FIG. 19B is illustrated to show a first axis (e.g., the x-axis) and a second axis (e.g., the y-axis), wherein the first axis and the second axis are orthogonal to each other. The first package component 100 may comprise two package structures 14 and two package components 50C disposed in a 2×2 type configuration. In an embodiment, the two package structures 14 are arranged such that edges of each package structure 14 having widths W3 are oriented to be parallel to the second axis (e.g., the y-axis) and edges of each package structure 14 having widths W4 are oriented to be parallel to the first axis (e.g., the x-axis), wherein the width W4 is greater than the width W3. The two package components 50C are arranged such that edges of each package component 50C having widths W5 are oriented to be parallel to the second axis (e.g., the y-axis) and edges of each package component 50C having widths W6 are oriented to be parallel to the first axis (e.g., the x-axis), wherein the width W6 is greater than the width W5. The package structures 14 and the package components 50C are disposed such that a first sidewall of each package structure 14 is adjacent to second sidewall of a package component 50C, wherein the first sidewall has the width W3 and the second sidewall has the width W5. In addition, a third sidewall of each package structures 14 is adjacent to fourth sidewall of a package component 50C, wherein the third sidewall has the width W4 and the second sidewall has the width W6. In addition, two package components 50B may be adjacent to each of the package structures 14 and the package components 50C, such that two package components 50B are adjacent to an edge of each package structure 14 that has the width W4, and two package components 50B are adjacent to an edge of each package component 50C that has the width W6. Each package structure 14 is physically isolated from the other package structure 14, the package components 50B and the package components 50C by the underfill 56. Each package component 50C is physically isolated from the other package component 50C, the package structures 14 and the package components 50B by the underfill 56. In addition, the package components 50B are physically isolated from each other by the underfill 56.

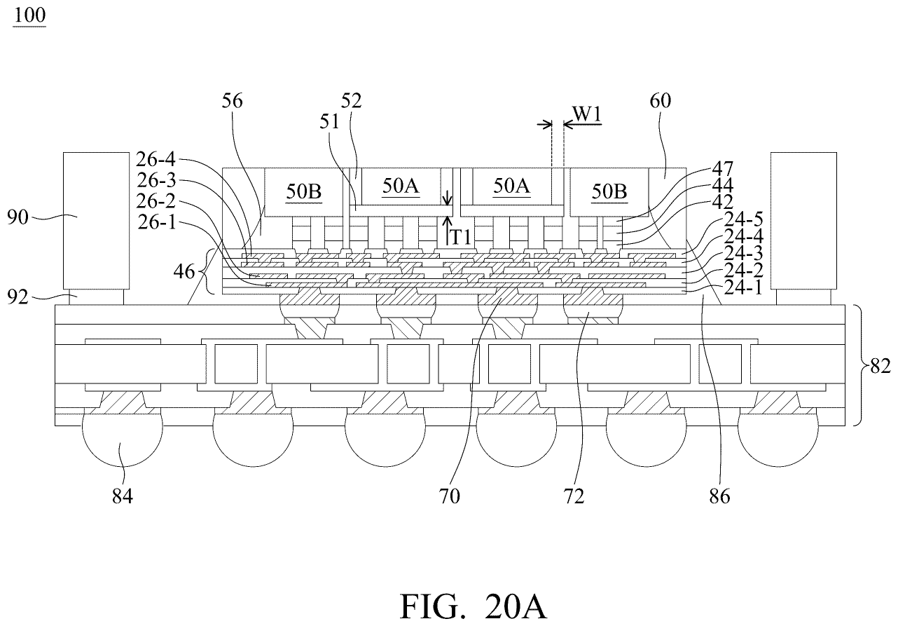

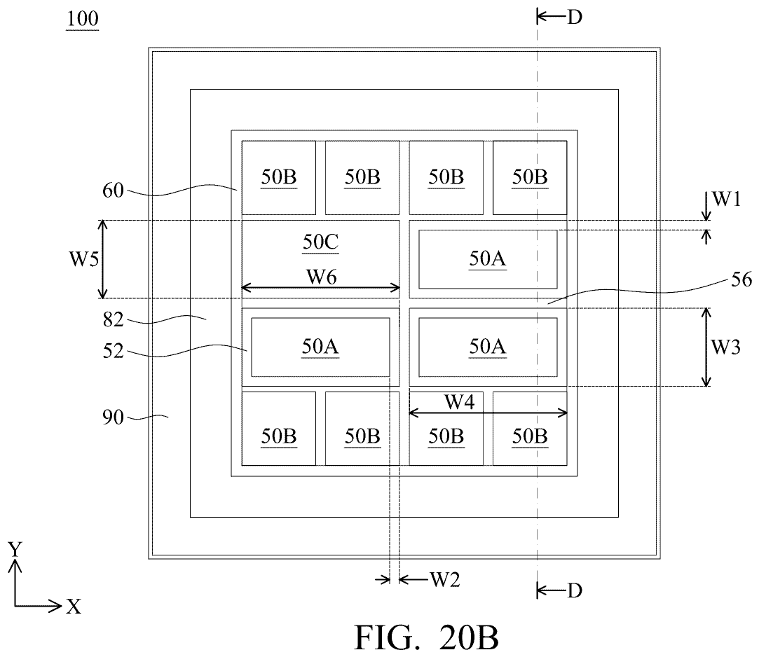

FIGS. 20A and 20B illustrate the first package component 100 in accordance with some other embodiments. Unless specified otherwise, like reference numerals in this embodiment (and subsequently discussed embodiments) represent like components in the embodiment shown in FIGS. 1 through 19B formed by like processes. Accordingly, the process steps and applicable materials may not be repeated herein.

FIG. 20A illustrates a cross-sectional view of the first package component 100 along a line D-D shown in FIG. 20B. FIG. 20B illustrates a top-down view of the first package component 100 shown in FIG. 20A. The FIG. 20B is illustrated to show a first axis (e.g., the x-axis) and a second axis (e.g., the y-axis), wherein the first axis and the second axis are orthogonal to each other. The first package component 100 may comprise three package structures 14 and one package component 50C disposed in a 2×2 type configuration. In an embodiment, the three package structures 14 are arranged such that edges of each package structure 14 having widths W3 are oriented to be parallel to the second axis (e.g., the y-axis) and edges of each package structure 14 having widths W4 are oriented to be parallel to the first axis (e.g., the x-axis), wherein the width W4 is greater than the width W3. The package component 50C is arranged such that edges of the package component 50C having widths W5 are oriented to be parallel to the second axis (e.g., the y-axis) and edges of the package component 50C having widths W6 are oriented to be parallel to the first axis (e.g., the x-axis), wherein the width W6 is greater than the width W5. The package structures 14 and the package component 50C are disposed such that a first sidewall of a first package structure 14 is adjacent to second sidewall of the package component 50C, wherein the first sidewall has the width W3 and the second sidewall has the width W5. In addition, a third sidewall of a second package structure 14 is adjacent to fourth sidewall of a third package structure 14, wherein the third sidewall has the width W3 and the fourth sidewall has the width W3. In addition, two package components 50B may be adjacent to each of the package structures 14 and the package component 50C, such that two package components 50B are adjacent to an edge of each package structure 14 that has the width W4, and two package components 50B are adjacent to an edge of each package component 50C that has the width W6. Each package structure 14 is physically isolated from the other package structures 14, the package components 50B and the package component 50C by the underfill 56. The package component 50C is physically isolated from the package structures 14 and the package components 50B by the underfill 56. In addition, the package components 50B are physically isolated from each other by the underfill 56.

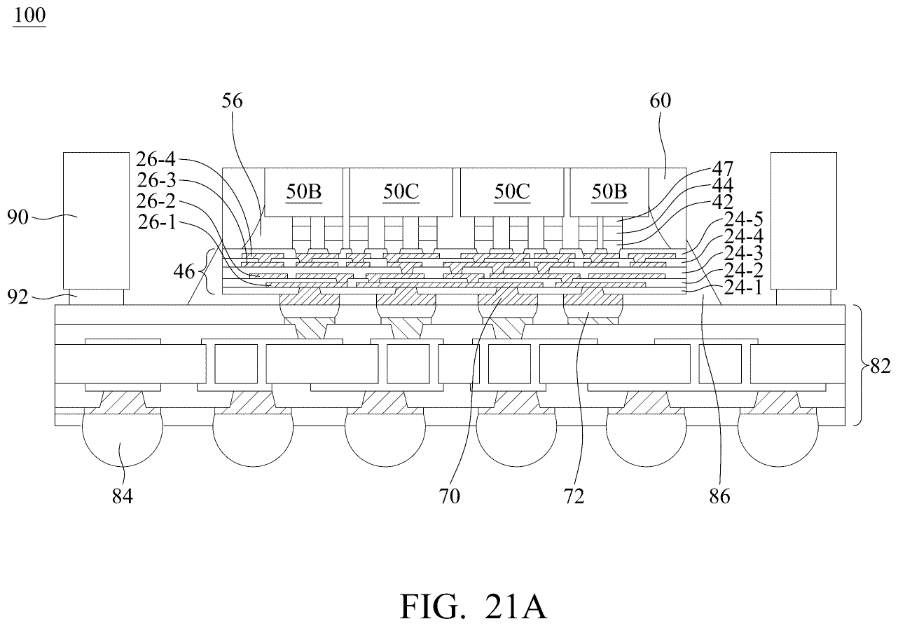

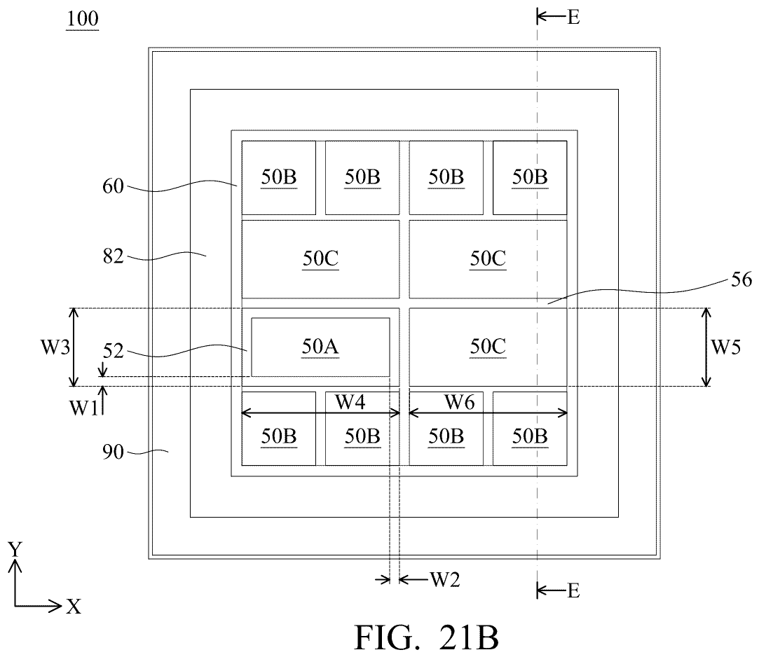

FIGS. 21A and 21B illustrate the first package component 100 in accordance with some other embodiments. Unless specified otherwise, like reference numerals in this embodiment (and subsequently discussed embodiments) represent like components in the embodiment shown in FIGS. 1 through 20B formed by like processes. Accordingly, the process steps and applicable materials may not be repeated herein.

FIG. 21A illustrates a cross-sectional view of the first package component 100 along a line E-E shown in FIG. 21B. FIG. 21B illustrates a top-down view of the first package component 100 shown in FIG. 21A. The FIG. 21B is illustrated to show a first axis (e.g., the x-axis) and a second axis (e.g., the y-axis), wherein the first axis and the second axis are orthogonal to each other. The first package component 100 may comprise one package structure 14 and three package components 50C disposed in a 2×2 type configuration. In an embodiment, the package structure 14 is arranged such that edges of the package structure 14 having widths W3 are oriented to be parallel to the second axis (e.g., the y-axis) and edges of the package structure 14 having widths W4 are oriented to be parallel to the first axis (e.g., the x-axis), wherein the width W4 is greater than the width W3. The package components 50C are arranged such that edges of the package components 50C having widths W5 are oriented to be parallel to the second axis (e.g., the y-axis) and edges of the package components 50C having widths W6 are oriented to be parallel to the first axis (e.g., the x-axis), wherein the width W6 is greater than the width W5. The package structure 14 and the package components 50C are disposed such that a first sidewall of the first package structure 14 is adjacent to a second sidewall of a first package component 50C, wherein the first sidewall has the width W3 and the second sidewall has the width W5. In addition, a third sidewall of a second package component 50C is adjacent to fourth sidewall of a third package component 50C, wherein the third sidewall has the width W5 and the fourth sidewall has the width W5. In addition, two package components 50B may be adjacent to each of the package structure 14 and the package components 50C, such that two package components 50B are adjacent to an edge of the package structure 14 that has the width W4, and two package components 50B are adjacent to an edge of each package component 50C that has the width W6. Each package component 50C is physically isolated from the other package components 50C, the package components 50B and the package structure 14 by the underfill 56. The package structure 14 is physically isolated from the package components 50C and the package components 50B by the underfill 56. In addition, the package components 50B are physically isolated from each other by the underfill 56.

The embodiments of the present disclosure have some advantageous features. The embodiments include the formation of an integrated circuit package that includes a package component comprising one or more semiconductor chip structures bonded to an interposer (also referred to as a redistribution structure), and a package substrate bonded to a side of the interposer opposing the one or more semiconductor chip structures. Each semiconductor chip structure comprises a molding compound that surrounds a semiconductor chip. In addition, the semiconductor chip structure comprises a redistribution structure that is electrically and physically coupled to a bottom surface of the semiconductor chip, such that the redistribution structure is disposed between the semiconductor chip and the interposer. Advantageous features of such embodiments include a reduction of a mismatch between a co-efficient of thermal expansion of the semiconductor chip structure and a co-efficient of thermal expansion of the interposer. As a result, a mismatch between a co-efficient of thermal expansion of the semiconductor chip structure and a co-efficient of thermal expansion of the interposer is reduced. This results in reduced warping of the integrated circuit package and a reduced risk of incomplete physical and electrical coupling of conductive connectors that are used to couple the interposer to the package substrate. In addition, a risk of electrical shorting between adjacent ones of the conductive connectors is reduced. As a result, the reliability and the performance of the integrated circuit package is improved.

In accordance with an embodiment, a method includes forming a first redistribution structure over a carrier, where forming the first redistribution structure includes forming a plurality of first organic polymer layers over the carrier; and forming a plurality of first conductive lines in the plurality of first organic polymer layers; attaching a first package structure to the first redistribution structure, the first package structure including a first semiconductor die; a molding material that surrounds an entirety of a perimeter of the first semiconductor die in a top-down view; and a second redistribution structure on bottom surfaces of the first semiconductor die and the molding material; dispensing a first underfill into a first gap between the plurality of first conductive lines and the first package structure; bonding a substrate to the first redistribution structure using first conductive connectors, the substrate being bonded to an opposing side of the first redistribution structure as the first package structure; and dispensing a second underfill into a second gap between the substrate and the first redistribution structure. In an embodiment, the second redistribution structure includes a second organic polymer layer on the bottom surfaces of the first semiconductor die and the molding material; and a second conductive line in the second organic polymer layer. In an embodiment, the plurality of first organic polymer layers and the second organic polymer layer include polybenzoxazole (PBO), polyimide or benzocyclobutene (BCB). In an embodiment, the second redistribution structure includes a thickness that is in a range from 2 μm to 50 μm. In an embodiment, the plurality of first conductive lines includes at least four redistribution layers (RDLs) in the plurality of first organic polymer layers. In an embodiment, a width of the molding material that surrounds the entirety of the perimeter of the first semiconductor die is in a range from 10 μm to 500 μm. In an embodiment, the method further includes adhering a stiffener ring on the substrate, where the stiffener ring encircles the first redistribution structure in a top view.

In accordance with an embodiment, a method includes attaching a first die and a second die to a carrier substrate; forming a molding material to fill in a gap between adjacent sidewalls of the first die and the second die, where the molding material surrounds an entirety of a perimeter of each of the first die and the second die; forming a first redistribution structure over top surfaces of the first die, the second die and the molding material; detaching the carrier substrate from the first redistribution structure; performing a singulation process to form a first package component and a second package component, the first package component including the first die, and the second package component including the second die, where after the singulation process a first width of the molding material that surrounds and is in physical contact with the entirety of the perimeter of each of the first die and the second die is in a range from 10 μm to 500 μm; and coupling the first package component and the second package component to a second redistribution structure. In an embodiment, the method further includes after coupling the first package component and the second package component to the second redistribution structure, dispensing an underfill into a gap between the first package component and the second package component. In an embodiment, the molding material includes first filler particles in a first base material, where the underfill includes second filler particles in a second base material, and where the first base material is different from the second base material. In an embodiment, the first redistribution structure has a thickness that is in a range from 2 μm to 50 μm. In an embodiment, the first redistribution structure and the second redistribution structure include organic polymers. In an embodiment, the second redistribution structure includes at least four redistribution layers (RDLs). 14. In an embodiment, each of the first package component and the second package component include a first sidewall having a second width and a second sidewall having a third width, where the second width is larger than the third width, where a fourth width of the second redistribution structure is larger than the second width, and where after coupling the first package component and the second package component to the second redistribution structure the first package component and the second package component are disposed such that the second sidewall of the first package component is adjacent to the second sidewall of the second package component. In an embodiment, the method further includes coupling a third die and a fourth die to the second redistribution structure, where the third die and the fourth die are adjacent to the first sidewall of the first package component; and coupling a fifth die and a sixth die to the second redistribution structure, where the fifth die and the sixth die are adjacent to the first sidewall of the second package component.

In accordance with an embodiment, a semiconductor device includes a first redistribution structure; a first package component bonded to the first redistribution structure, the first package component including a second redistribution structure; a first die coupled to the second redistribution structure; and a molding material on the second redistribution structure, where the molding material surrounds and is in physical contact with an entirety of a perimeter of the first die; a second die bonded to a same surface of the first redistribution structure as the first package component; an underfill between the first package component and the second die, where the molding material includes a first material, and where the underfill includes a second material different from the first material; and an encapsulant that encapsulates the first package component and the second die, where the encapsulant includes a third base material and a plurality of silica fillers in the third base material. In an embodiment, the second redistribution structure has a thickness that is in a range from 2 μm to 50 μm. In an embodiment, the first package component includes a first sidewall having a first width and a second sidewall having a second width, where the first width is larger than the second width, where the first sidewall is parallel to a first axis and the second sidewall is parallel to a second axis, where the first axis is orthogonal to the second axis, where a first portion of the molding material in physical contact with the first sidewall has a third width measured in a direction parallel to the second axis, and where a second portion of the molding material in physical contact with the second sidewall has a fourth width measured in a direction parallel to the first axis, and where the third width and the fourth width are equal. In an embodiment, the first package component includes a first sidewall having a first width and a second sidewall having a second width, where the first width is larger than the second width, wherein the first sidewall is parallel to a first axis and the second sidewall is parallel to a second axis, where the first axis is orthogonal to the second axis, where a first portion of the molding material in physical contact with the first sidewall has a third width measured in a direction parallel to the second axis, and where a second portion of the molding material in physical contact with the second sidewall has a fourth width measured in a direction parallel to the first axis, and where the third width and the fourth width are different. In an embodiment, the second die is a bare die.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a first redistribution structure;
a first package component bonded to the first redistribution structure, the first package component comprising:
a second redistribution structure;
a first die coupled to the second redistribution structure; and
a molding material on the second redistribution structure, wherein the molding material surrounds and is in physical contact with an entirety of a perimeter of the first die;
a second die bonded to a same surface of the first redistribution structure as the first package component;
an underfill between the first package component and the second die, wherein the molding material comprises a first material, and wherein the underfill comprises a second material different from the first material; and
an encapsulant that encapsulates the first package component and the second die, wherein the encapsulant comprises a third base material and a plurality of silica fillers in the third base material.

2. The semiconductor device of claim 1, wherein the second redistribution structure has a thickness that is in a range from 2 μm to 50 μm.

3. The semiconductor device of claim 1, wherein the first package component comprises a first sidewall having a first width and a second sidewall having a second width, wherein the first width is larger than the second width, wherein the first sidewall is parallel to a first axis and the second sidewall is parallel to a second axis, wherein the first axis is orthogonal to the second axis, wherein a first portion of the molding material in physical contact with the first sidewall has a third width measured in a direction parallel to the second axis, and wherein a second portion of the molding material in physical contact with the second sidewall has a fourth width measured in a direction parallel to the first axis, and wherein the third width and the fourth width are equal.

4. The semiconductor device of claim 1, wherein the first package component comprises a first sidewall having a first width and a second sidewall having a second width, wherein the first width is larger than the second width, wherein the first sidewall is parallel to a first axis and the second sidewall is parallel to a second axis, wherein the first axis is orthogonal to the second axis, wherein a first portion of the molding material in physical contact with the first sidewall has a third width measured in a direction parallel to the second axis, and wherein a second portion of the molding material in physical contact with the second sidewall has a fourth width measured in a direction parallel to the first axis, and wherein the third width and the fourth width are different.

5. The semiconductor device of claim 1, wherein the second die is a bare die.

6. A semiconductor device comprising:
a first package component and a first die bonded to a first side of a first redistribution structure, wherein the first redistribution structure comprises a plurality of insulating layers and a plurality of redistribution lines (RDLs), wherein each insulating layer of the plurality of insulating layers comprises an organic material, wherein the first package component comprises:
a second redistribution structure;
a second die coupled to the second redistribution structure; and
a molding material on the second redistribution structure and surrounding the second die; and
an encapsulant that encapsulates the first package component and the first die.

7. The semiconductor device of claim 6, further comprising:
an underfill between the first package component and the first die, wherein the molding material comprises a first material, and wherein the underfill comprises a second material different from the first material.

8. The semiconductor device of claim 6, wherein the second redistribution structure has a thickness that is in a range from 2 μm to 50 μm.

9. The semiconductor device of claim 6, wherein a width of the molding material from a point adjacent to a sidewall of the second die to a point on an outermost sidewall of the first package component is in a range from 10 μm to 500 μm.

10. The semiconductor device of claim 6, wherein the plurality of insulating layers comprises at least 5 insulating layers.

11. The semiconductor device of claim 10, wherein the plurality of redistribution lines (RDLs) comprises at least 4 redistribution lines (RDLs).

12. The semiconductor device of claim 6, wherein each insulating layer of the plurality of insulating layers comprises polybenzoxazole (PBO), polyimide or benzocyclobutene (BCB).

13. The semiconductor device of claim 6, further comprising:
a second package component bonded to a second side of the first redistribution structure, wherein the second package component comprises a substrate core.

14. The semiconductor device of claim 13, further comprising:
a stiffener ring attached to the second package component, wherein the stiffener ring encircles the first package component, the first die, and the first redistribution structure in a top view.

15. A semiconductor device comprising:
a first package component bonded to a first side of a first redistribution structure, wherein the first package component comprises a substrate core;
a second package component and a first die bonded to a second side of the first redistribution structure, wherein the second package component comprises:
a second redistribution structure;
a second die coupled to the second redistribution structure; and
a molding material on the second redistribution structure and on sidewalls of the second die; and
an encapsulant disposed over the first package component, wherein the encapsulant surrounds the second package component and the first die.

16. The semiconductor device of claim 15, further comprising:
a stiffener ring over and attached to the first package component, wherein the stiffener ring encircles the first redistribution structure in a top view.

17. The semiconductor device of claim 15, wherein the first redistribution structure comprises a plurality of insulating layers and a plurality of redistribution lines (RDLs), wherein each insulating layer of the plurality of insulating layers comprises an organic material.

18. The semiconductor device of claim 17, wherein each insulating layer of the plurality of insulating layers comprises polybenzoxazole (PBO), polyimide or benzocyclobutene (BCB).

19. The semiconductor device of claim 15, wherein the second redistribution structure has a thickness that is in a range from 2 μm to 50 μm.

20. The semiconductor device of claim 15, wherein a width of the second redistribution structure is greater than a width of the second die.
